(19) United States
(12) Patent Application Publication
(10) Pub. No.: US 2026/0123078 A1
(43) Pub. Date: Apr. 30, 2026

(54) SEMICONDUCTOR STRUCTURE AND METHOD OF FORMING THE SAME

(71) Applicant: Taiwan Semiconductor Manufacturing Company, Ltd., Hsinchu (TW)

(72) Inventors: Che Wei Yang, New Taipei City (TW); Ming-Che Lee, Tainan City (TW); Guanyu Luo, Chiayi County (TW); Sheng-Chan Li, Tainan City (TW); Sheng-Chau CHEN, Tainan City (TW); Chung-Yi Yu, Hsin-Chu (TW); Cheng-Yuan Tsai, Hsin-Chu county (TW)

(73) Assignee: Taiwan Semiconductor Manufacturing Company, Ltd., Hsinchu (TW)

(21) Appl. No.: 18/926,231

(22) Filed: Oct. 24, 2024

(51) Int. Cl. H01L 27/146

(52) U.S. Cl. CPC H10F 39/8067; H10F 39/024; H10F 39/182; H10F 39/806; H10F 39/807; H10F 39/811

(57) ABSTRACT

A method of forming a semiconductor structure includes: forming a trench in a substrate; forming a dielectric layer over the substrate in the trench; forming a diffusion barrier layer on the dielectric layer and in the trench; forming a metal blanket layer on the diffusion barrier layer and in the trench; forming a metal seed layer on the metal blanket layer and in the trench; forming a high-reflectivity metal layer in the trench by using the metal seed layer as a seed; and removing the diffusion barrier layer, the metal blanket layer, the metal seed layer and the high-reflectivity metal layer outside of the trench.

### BACKGROUND

The semiconductor industry has experienced rapid growth due to continuous improvements in the integration density of various electronic components (e.g., transistors, diodes, resistors, capacitors, etc.). For the most part, this improvement in integration density has come from repeated reductions in minimum feature size, which allows more of the smaller components to be integrated into a given area. These smaller electronic components also require smaller packages that utilize less area than previous packages. Although existing semiconductor structures have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 13 illustrate schematic cross-sectional views of a method of forming a semiconductor structure in accordance with some embodiments.

FIG. 14A and FIG. 14B illustrate enlarged local views of deep trench isolation regions in accordance with some embodiments.

FIG. 15 illustrates a schematic cross-sectional view of a semiconductor structure in accordance with some embodiments.

FIG. 16 illustrates a circuit diagram of a pixel unit in accordance with some embodiments.

FIG. 17 illustrates a schematic cross-sectional view of a semiconductor structure in accordance with other embodiments.

FIG. 18 illustrates a process flow for forming a deep trench isolation region in accordance with some embodiments.

FIG. 19 illustrates a process flow for forming a semiconductor structure in accordance with some embodiments.

FIG. 20 illustrates a schematic cross-sectional view of a semiconductor structure in accordance with other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to a semiconductor structure including a Deep Trench Isolation (DTI) region and a method of forming the same. The intermediate stages of forming the semiconductor structure are illustrated in accordance with some embodiments. Some variations of some embodiments are discussed. Throughout the various views and illustrative embodiments, like reference numbers are used to designate like elements. The DTI region of the present disclosure is void-free and includes a high-reflectivity metallic material. Accordingly, with the use of the high-reflectivity metallic material, the quantum efficiency of the image sensors is improved. The DTI structure may be used for Backside Illumination (BSI) Complementary Metal-Oxide-Semiconductor (CMOS) image sensors or Front Side Illumination (FSI) CMOS image sensors, and may be used in other application in which deep trench isolation regions are used.

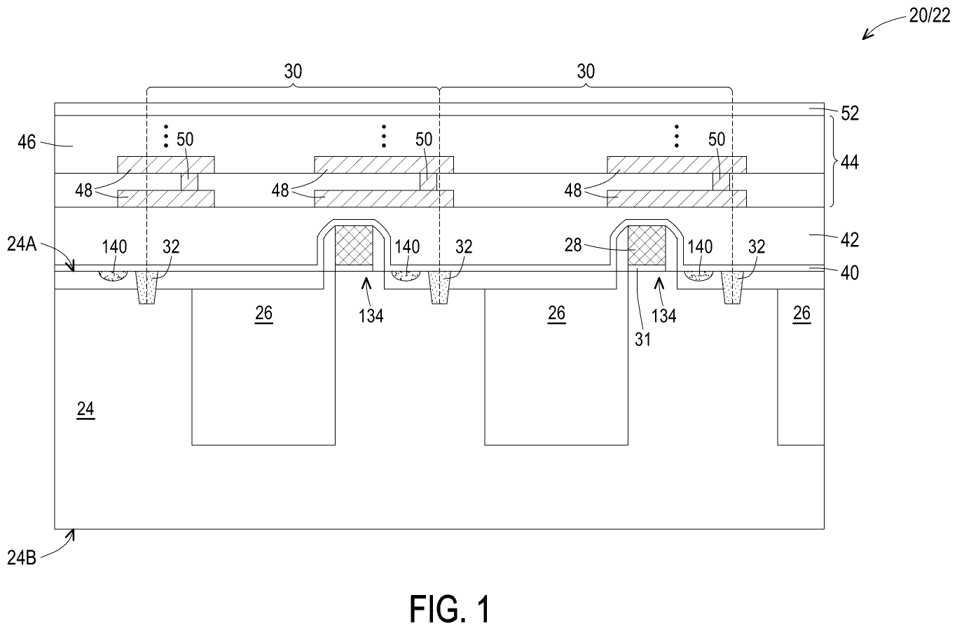

FIG. 1 to FIG. 13 illustrate schematic cross-sectional views of a method of forming a semiconductor structure in accordance with some embodiments. It is understood that the present disclosure is not limited by the method described below. Additional operations can be provided before, during, and/or after the method and some of the operations described below can be replaced or eliminated, for additional embodiments of the methods. Although FIG. 1 to FIG. 13 are described in relation to a method, it is appreciated that the structures disclosed in FIG. 1 to FIG. 13 are not limited to such a method, but instead may stand alone as structures independent of the method.

FIG. 1 illustrates the formation of an initial structure of an image sensor chip 20, which may be a part of wafer 22 that includes multiple image sensor chips 20 therein. The image sensor chip 20 includes a semiconductor substrate 24. In some embodiments, the semiconductor substrate 24 is a crystalline silicon substrate. In other embodiments, the semiconductor substrate 24 includes an elementary semiconductor such as germanium; a compound semiconductor including silicon carbon, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates such as multi-layered or gradient substrates may also be used. Throughout the description, a surface 24A of the semiconductor substrate 24 is referred to as a front surface of the semiconductor substrate 24, and a surface 24B is referred to as a back surface of the semiconductor substrate 24. The surfaces 24A and 24B may be on (100) or (001) surface planes.

Shallow Trench Isolation (STI) regions 32 are formed extending into the semiconductor substrate 24 to define active regions for circuits. In some embodiments, from a top view, the STI regions 32 may form a grid including horizontal strip portions and vertical strip portions crossing each other.

Referring back to FIG. 1, photosensitive regions 26 are formed extending from the front surface 24A into the semiconductor substrate 24. The formation of the photosensitive regions 26 may include performing an implantation process. The photosensitive regions 26 are configured to convert light signals (photons) into electrical signals. The photosensitive regions 26 may include PN junction photo-diodes, PNP photo-transistors, NPN photo-transistors, or the like. The photosensitive regions 26 are alternatively referred to as “image sensors” in some examples. In some embodiments, the photosensitive regions 26 form an image sensor array.

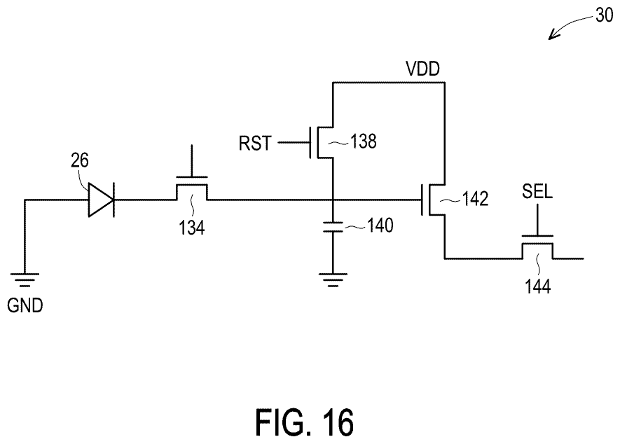

FIG. 1 also illustrates pixel units 30, which may include at least portions in the active regions defined by the STI regions 32. FIG. 16 illustrates a circuit diagram of a pixel unit 30 in accordance with some embodiments. In some embodiments, the pixel unit 30 includes a photosensitive region 26, which has an anode coupled to an electrical ground GND, and a cathode coupled to a source of a transfer gate transistor 134. The drain of the transfer gate transistor 134 may be coupled to a drain of a reset transistor 138 and a gate of a source follower 142. The reset transistor 138 has a gate coupled to a reset line RST. A source of the reset transistor 138 may be coupled to a pixel power supply voltage VDD. A floating diffusion capacitor 140 may be coupled between the source/drain of the transfer gate transistor 134 and the gate of the source follower 142. The reset transistor 138 is used to preset the voltage at the floating diffusion capacitor 140 to VDD. A drain of the source follower 142 is coupled to a power supply voltage VDD. A source of the source follower 142 is coupled to a row selector 144. The source follower 142 provides a high-impedance output for the pixel unit 30. The row selector 144 functions as a select transistor of the respective pixel unit 30, and the gate of the row selector 144 is coupled to a select line SEL.

Referring back to FIG. 1, a transistor is illustrated as an example of the devices (such as 134, 138, 142, and 144 in FIG. 16) in the pixel unit 30. For example, the transfer gate transistor 134 is illustrated in FIG. 1. In some embodiments, each of photosensitive region 26 is electrically coupled to a first source/drain region of transfer gate transistor 134, which includes a gate 28 and a gate dielectric 31. The gate dielectric 31 is in contact with the front surface 24A of the semiconductor substrate 24. The first source/drain region of the transfer gate transistor 134 may be shared by the corresponding connecting photosensitive region 26. The floating diffusion capacitor 140 is formed in the semiconductor substrate 24, for example, through implanting into the semiconductor substrate 24 to form a p-n junction, which acts as a floating diffusion node. The floating diffusion capacitor 140 may be formed in a second source/drain region of the transfer gate transistor 134, and hence one of the capacitor plates of the floating diffusion capacitor 140 is electrically coupled to the second source/drain region of the transfer gate transistor 134. The photosensitive region 26, the respective transfer gate transistors 134 and the floating diffusion capacitors 140 in the same active region form pixel units 30 as also marked in FIG. 1.

A Contact Etch Stop Layer (CESL) 40 is formed on the semiconductor substrate 24 and the transistors such as the transfer gate transistors 134. An Inter-Layer dielectric (ILD) 42 is formed over the CESL 40. The CESL 40 may include aluminum nitride, aluminum oxide, aluminum oxynitride, silicon nitride, silicon carbide or a combination thereof. The ILD 42 may include silicon oxide, silicon oxynitride, silicon oxycarbide or a low-k material having a dielectric constant less than 3.5 or 2.5.

A front-side interconnect structure 44 is formed over the semiconductor substrate 24. The front-side interconnect structure 44 is used to electrically interconnect the devices in the image sensor chip 20. The front-side interconnect structure 44 includes dielectric layers 46, and metal lines 48 and vias 50 in the dielectric layers 46. The metal lines 48 and vias 50 include Cu, Al, Co, Cr, W, Ti, Ta, TiN, TaN, the like or a combination thereof. Throughout the description, the metal lines 48 in a same dielectric layer 46 are collectively referred to as being a metal layer. The front-side interconnect structure 44 may include multiple metal layers. In some embodiments, the dielectric layers 46 include silicon oxide, silicon oxynitride, silicon oxycarbide or a low-k material having a dielectric constant less than 3.5 or 2.5. A passivation layer 52 is formed over the dielectric layers 46. The passivation layer 52 may include a polymer material or a dielectric material, or a combination thereof. In some embodiments, the passivation layer 52 may include a polymer material such as polybenzoxazole (PBO), polyimide (PI), benzocyclobutene (BCB), the like, or a combination thereof. In some embodiments, the passivation layer 52 may include silicon oxide, silicon nitride, the like, or a combination thereof. The passivation layer 52 may function as a bonding layer for bonding the underlying structure to another semiconductor substrate (not shown). Some transistors such as reset transistors, select transistors, and the like may be formed on the another semiconductor substrate.

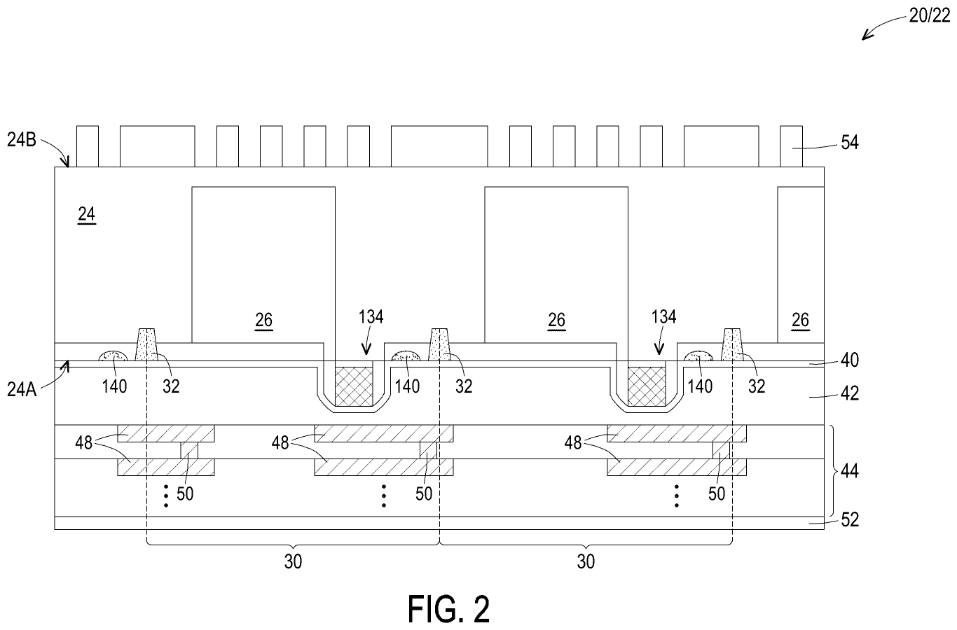

Referring to FIG. 2, the wafer 22 is flipped upside down. A backside grinding is performed from the back surface 24B, so as to thin the semiconductor substrate 24. The thickness of the semiconductor substrate 24 may be reduced to smaller than about 10 μm, or smaller than about 5 μm, for example. With the semiconductor substrate 24 having a small thickness, light can penetrate from the back surface 24B into the semiconductor substrate 24, and reach the photosensitive regions 26.

Thereafter, a hard mask 54 is formed on the back surface 24B of the semiconductor substrate 24. In some embodiments, the hard mask 54 includes silicon nitride, titanium nitride, or the like. A photo resist (not shown) may be formed on the hard mask 54 and then patterned, and the hard mask 54 is patterned using the photo resist as an etching mask.

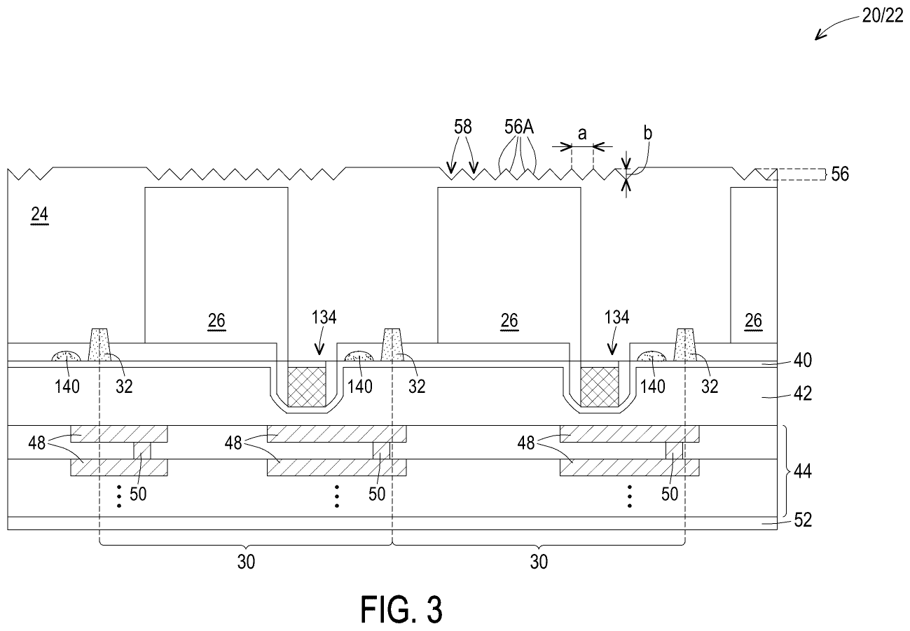

Referring to FIG. 3, an etching process is performed, using the hard mask 54 as an etching mask, so as to form pyramids 56 on the back side of the semiconductor substrate 24. The etching process may include a wet etching process, which may be performed using KOH, Tetra Methyl Ammonium Hydroxide (TMAH), or the like as an etchant. Since the etching rates of the semiconductor substrate 24 on different surface planes are different from each other, slant surfaces 56A are formed, for example, on (111) surface planes. Recesses 58 are formed extending into the semiconductor substrate 24.

With the proceeding of the etching of the semiconductor substrate 24, slant surfaces 56A are recessed, and opposite surfaces 56A facing the same recess 58 eventually meet with each other to have a V-shape. In some embodiments, the hard mask 54 is removed after the recesses 58 start extending directly underlying hard mask 54, followed by another wet etching to further extend recesses 58 down until the top portions of semiconductor substrate 24 form pyramids. In other embodiments, the hard mask 54 is consumed during the wet etching so that a single wet etching process may result in the structure as shown in FIG. 3. In some embodiments, the hard mask 54 is removed when the recesses 58 start extending directly underlying hard mask 54, and no more etching of the semiconductor substrate 24 is performed after hard mask 54 is removed.

After the etching, pyramids 56 are formed, with each of pyramids including four sides. Each of the four sides has a triangular shape. In some embodiments, the depth b of the recesses 58 is in the range between about 10 nm to 1,000 nm. The width b between adjacent peaks of the pyramids 56 may be in the range between about 10 nm to 1,000 nm. In other embodiments, instead of having pyramid shapes, pseudo pyramids are formed, which include small planar platforms at the top, which planar platforms are formed since the portions of the semiconductor substrate 24 directly underlying hard mask 54 are not fully etched. Accordingly, the resulting structure will have a trapezoidal cross-sectional view shape. In subsequent discussion, pyramids are used as examples, and other shapes of the top portions of the semiconductor substrate 24 are contemplated. When viewed from top, the pyramids (or pseudo pyramids) may form an array.

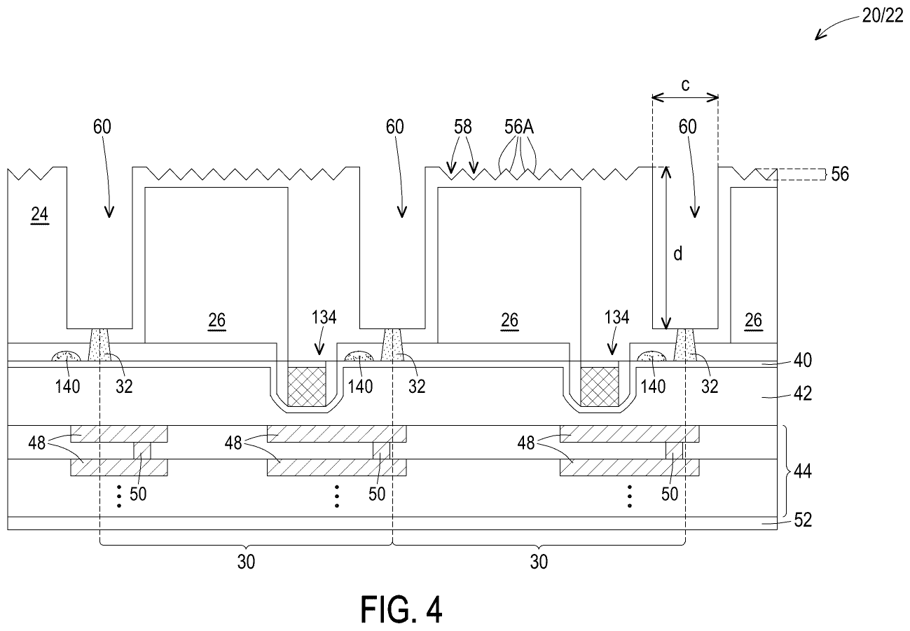

Referring to FIG. 4, an etching process is performed to form multiple trenches 60. The etching is performed through an anisotropic etching process. In some embodiments, the sidewalls of the trenches 60 are straight and vertical, and the sidewalls are substantially perpendicular to the surface (e.g., back surface) of the semiconductor substrate 24. However, the present disclosure is not limited thereto. In other embodiments, the sidewalls of the trenches 60 may be slightly tilted or curved with respect to the surface (e.g., back surface) of the semiconductor substrate 24.

In some embodiments, the etching is performed through a dry etching method including, for example but not limited to, Inductively Coupled Plasma (ICP), Transformer Coupled Plasma (TCP), Electron Cyclotron Resonance (ECR), Reactive Ion Etch (RIE), or the like. The process gases include, for example, fluorine-containing gases (such as SF₆, CF₄, CHF₃, NF₃), chlorine-containing gases (such as Cl₂), Br₂, HBr, BCl₃, and/or the like. When viewed from top of the wafer 22, the trenches 60 form a grid. Furthermore, the trenches 60 may overlap the corresponding STI regions 32, which also form a grid. In some embodiments, the trenches 60 may expose the corresponding STI regions 32, as shown in FIG. 4. However, the present disclosure is not limited thereto. In other embodiments, the trenches 60 may be spaced apart from the respective underlying STI regions 32 by a small distance, for example, smaller than about 0.5 μm.

In some embodiments, the depth d of the trenches 60 may be equal to or greater than about 500 nm, equal to or greater than about 3,000 nm, equal to or greater than 10,000 nm, or even more. The width c of the trenches 60 may be equal to or less than about 100 nm, equal to or less than about 50 nm, equal to or less than about 30 nm, or even less. The aspect ratio (=d/c) of the trenches 60 may be greater than about 50, greater than about 100, greater than about 130 or higher, for example. In some embodiments, the trenches 60 have sharp bottom corners, as shown in FIG. 4. However, the present disclosure is not limited thereto. In other embodiments, the bottom surfaces of the trenches 60 are rounded and have a U-shape or a V-shape in the cross-sectional view.

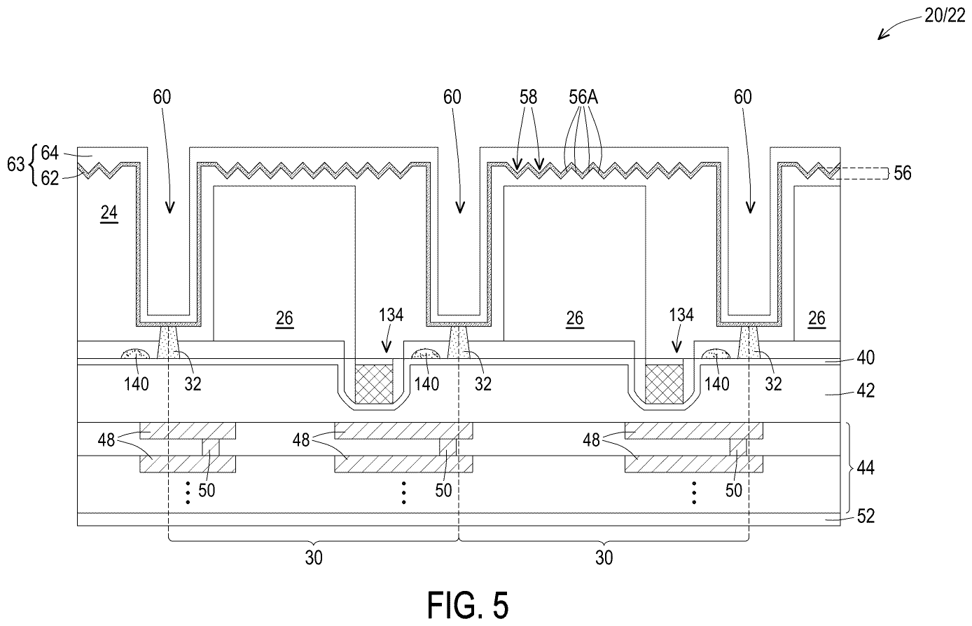

Referring to FIG. 5, a high-k layer 62 is formed in the trenches 60. In some embodiments, the high-k layer 62 has a dielectric constant greater than about 10 and includes a dielectric material having a good reflection property. In some embodiments, the high-k layer 62 may include aluminum oxide (Al₂O₃), hafnium oxide (HfO₂), tantalum oxide (Ta₂O₅), or the like, or a combination thereof. The high-k layer 62 may be formed using a conformal deposition method such as Atomic Layer Deposition (ALD) or Chemical Vapor Deposition (CVD), for example. The high-k layer 62 is conformally formed along the sidewalls and bottoms of the trenches 60, in contact with the STI regions 32, and along the slanted surfaces 56A of the pyramids 56. In some embodiments, the thickness of the high-k layer 62 is in the range between about 10 angstroms to 200 angstroms.

Still referring to FIG. 5, an insulating layer 64 is formed on the high-k layer 62 and in the trenches 60. In some embodiments, the insulating layer 64 includes an insulating material having a good insulating property. In some embodiments, the insulating layer 64 includes silicon oxide, silicon oxynitride, silicon oxycarbide, or a combination thereof. In some embodiments, the insulating layer 64 may be formed using a conformal deposition method such as Atomic Layer Deposition (ALD) or Chemical Vapor Deposition (CVD), for example. In other embodiments, the formation of the insulating layer 64 may be achieved through a non-conformal and none bottom-up deposition method, so that recesses 58 of the pyramids 56 are fully filled. The sidewalls and bottoms of the trenches 60 are lined with the insulating layer 64. In some embodiments, voids or air gaps (no shown) are formed in trenches 60, and are sealed by the insulating layer 64. For example, the insulating layer 64 may be formed using High-Density Plasma (HDP) Chemical Vapor Deposition (CVD). In some embodiments, a planarization process such as a Chemical Mechanical Polish (CMP) process or a mechanical grinding process is performed to remove portions of the insulating layer 64 and reveal the voids. In some embodiments, the thickness of the insulating layer 64 is in the range between about 10 angstroms to 200 angstroms. In some embodiments, the high-k layer 62 and the insulating layer 64 are collectively referred to as a composite dielectric layer 63.

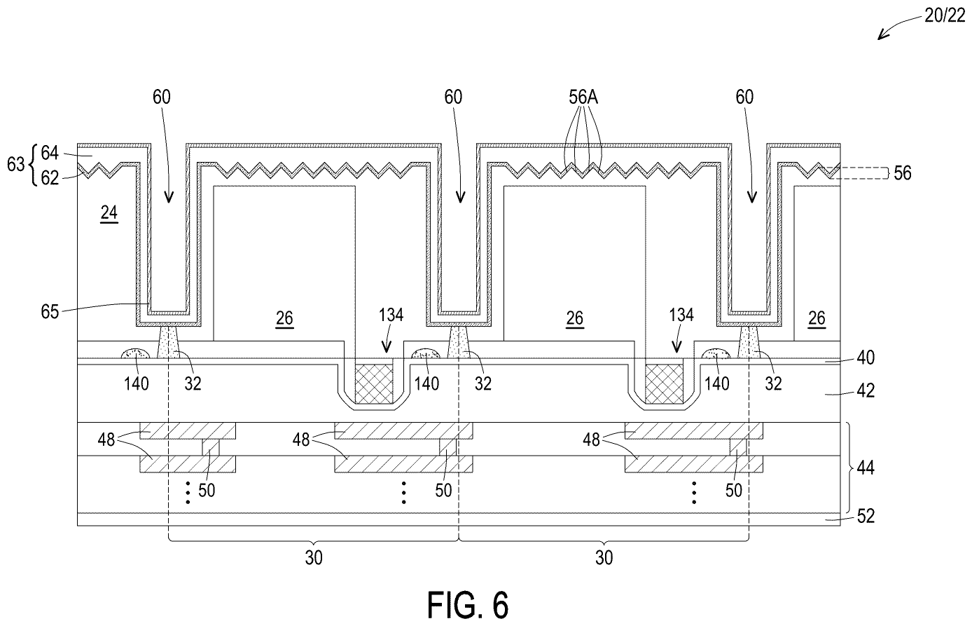

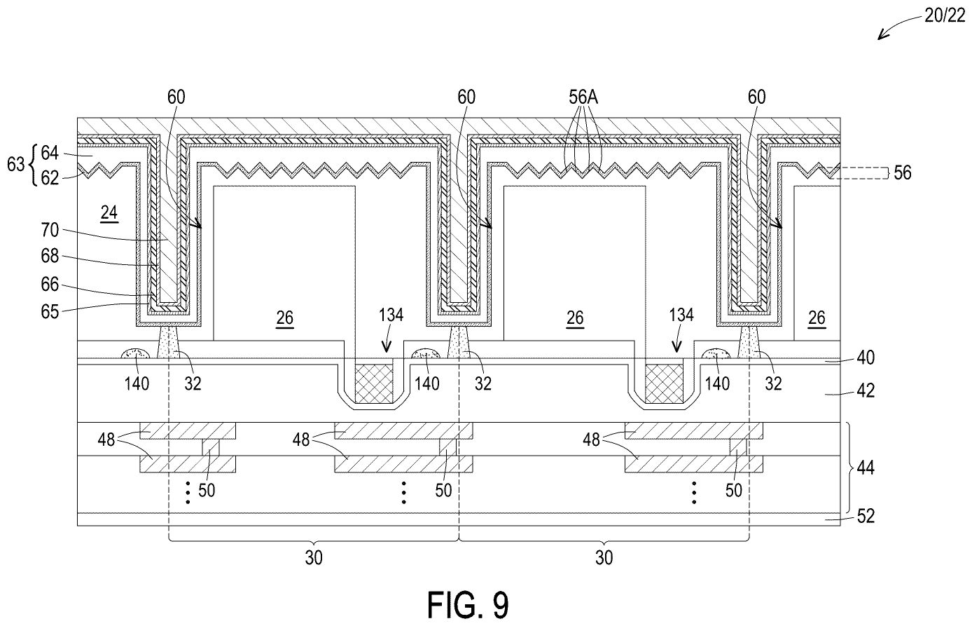

Referring to FIG. 6, a diffusion barrier layer 65 is formed on the insulating layer 64 and in the trenches 60. In some embodiments, the diffusion barrier layer 65 is formed of a material that can effectively prevent the subsequently formed high-reflectivity metal layer 70 (FIG. 9) from diffusing into the semiconductor substrate 24. In some embodiments, the diffusion barrier layer 65 includes TiN, TaN, TiAl, Mo₂N, RuO₂ or a combination thereof. The diffusion barrier layer 65 may be formed using a conformal deposition method such as Atomic Layer Deposition (ALD) or Chemical Vapor Deposition (CVD), for example. The diffusion barrier layer 65 is conformally formed over the insulating layer 64, along the sidewalls and bottoms of the trenches 60, and over the tops of the pyramids 56. In some embodiments, the thickness of the diffusion barrier layer 65 is in the range between about 10 angstroms to 200 angstroms.

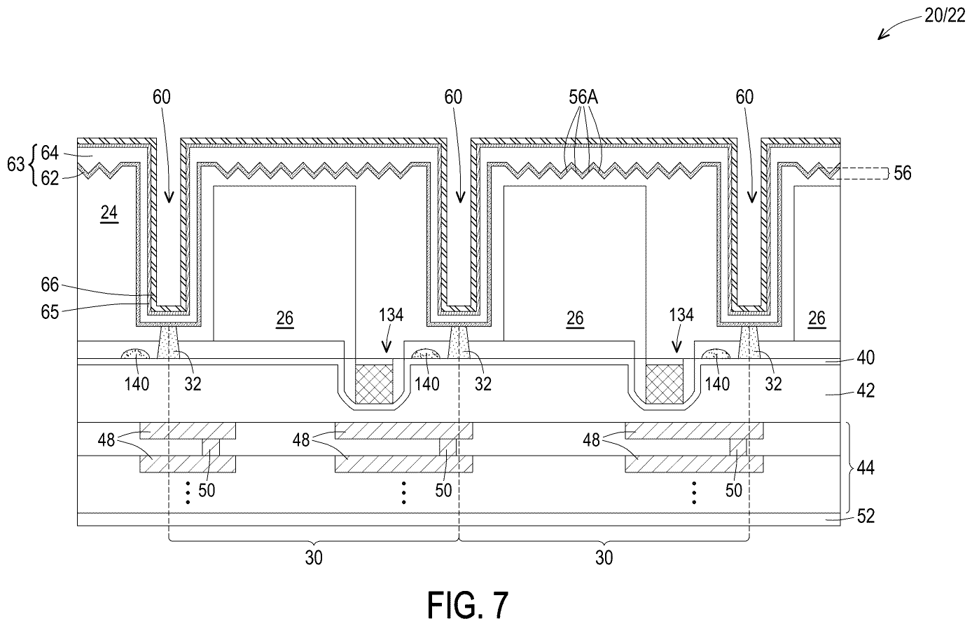

Referring to FIG. 7, a metal blanket layer 66 is formed on the diffusion barrier layer 65 and in the trenches 60. In some embodiments, the metal blanket layer 66 is formed of a good surface coverage material that can effectively provide a planar surface for the subsequently formed high-reflectivity metal layer 70 (FIG. 9). The surface coverage is defined as the number of adsorbed molecules on a surface divided by the number of molecules in a filled monolayer on that surface. The material and functionality of the metal blanket layer 66 is different from the material and functionality of the diffusion barrier layer 65. In some embodiments, the metal blanket layer 66 includes Co, Ru, Mo, Al, Au, W, Ta or a combination thereof. The metal blanket layer 66 may be formed using a conformal deposition method such as Atomic Layer Deposition (ALD) or Chemical Vapor Deposition (CVD), instead of the conventional sputtering method, for example. The metal blanket layer 66 is conformally formed over the diffusion barrier layer 65, along the sidewalls and bottoms of the trenches 60, and over the tops of the pyramids 56. In some embodiments, the thickness of the metal blanket layer 66 is in the range between about 20 angstroms to 300 angstroms. In some embodiments, the thickness of the metal blanket layer 66 is greater than (e.g., at least two times) the thickness of the diffusion barrier layer 65, so as to provide a fully covered metal surface for the subsequent electroplating process. For examples, the thickness of the metal blanket layer 66 is about 50 angstroms, and the thickness of the diffusion barrier layer 65 is about 20 angstroms.

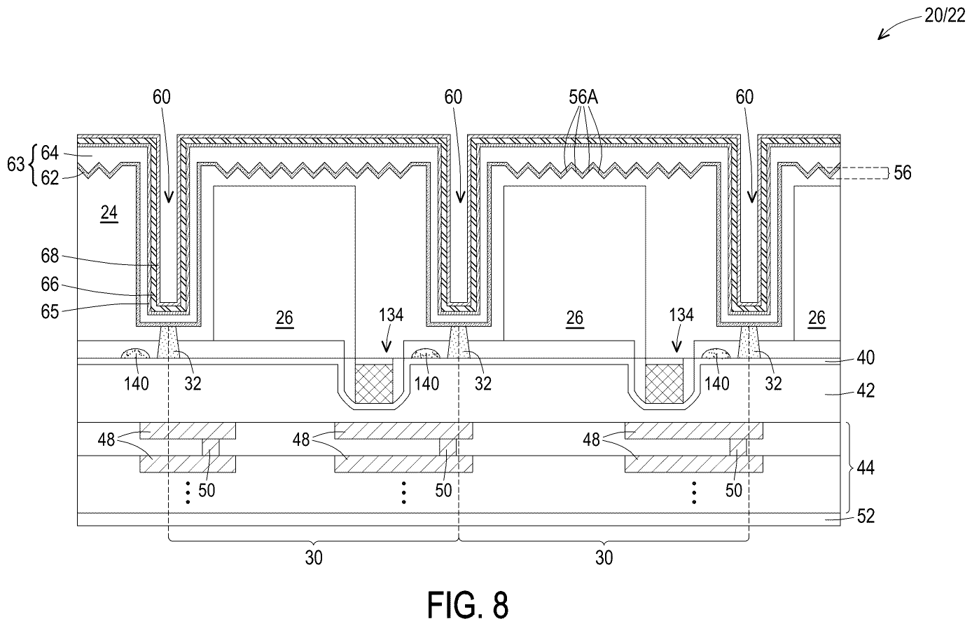

Referring to FIG. 8 and FIG. 9, a high-reflectivity metal layer 70 is formed in the trenches 60 over the metal blanket layer 66. In some embodiments, the formation method includes forming a metal seed layer 68 (FIG. 8), and plating the high-reflectivity metal layer 70 by using the metal seed layer 68 as a seed. The metal seed layer 68 may include Cu. The material of the high-reflectivity metal layer 70 includes a material that has a high reflectivity, for example, higher than about 90 percent at a wavelength greater than about 600 nm or greater than about 800 nm. For examples, the high-reflectivity metal layer 70 includes Cu, AlCu or a copper allay. The metal seed layer 68 may be formed using a conformal deposition method such as Atomic Layer Deposition (ALD) or Chemical Vapor Deposition (CVD), instead of the conventional sputtering method, for example. In some embodiments, the thickness of the metal seed layer 68 is in the range between about 10 angstroms to 300 angstroms. In some embodiments, the thickness of the metal seed layer 68 is equal to or greater than the thickness of the metal blanket layer 66. For examples, the thickness of the metal seed layer 68 is about 100 angstroms, and the thickness of the metal blanket layer 66 is about 50 angstroms. However, the present disclosure is not limited thereto. In other embodiments, the thickness of the metal seed layer 68 is less than the thickness of the metal blanket layer 66. In some embodiments, the formation of the metal seed layer 68 may be omitted as needed. For example, when the metal blanket layer 66 (e.g., Co, Ru or Au) can function as a seed layer, the formation of the metal seed layer 68 is omitted, and the high-reflectivity metal layer 70 is directly plated on the metal blanket layer 66 by using the metal blanket layer 66 as a seed. In some embodiments, the thickness of the high-reflectivity metal layer 70 is in the range between about 10 angstroms to 500 angstroms. In some embodiments, the high-reflectivity metal layer 70 completely fills the trenches 60.

In some embodiments, the diffusion barrier layer 65, the metal blanket layer 66 and the metal seed layer 68 may be formed sequentially in the same process stage using the same ALD or CVD process chamber. By such manner, the process steps are simplified without moving the wafer back and forth between different process stages and/or chambers.

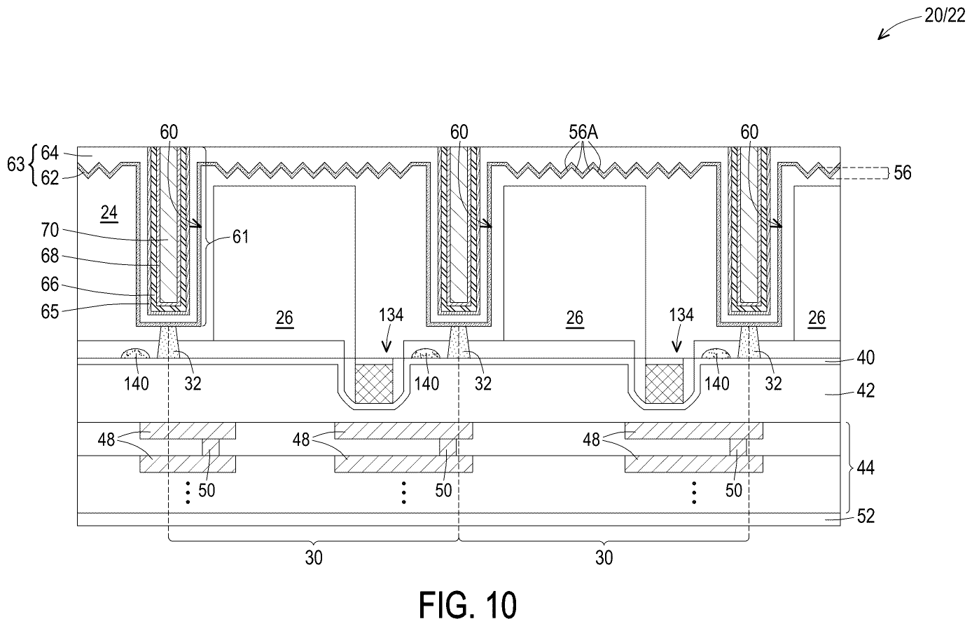

Referring to FIG. 10, a planarization process such as a CMP process or a mechanical grinding process is performed to remove excess portions of the layers 65, 66, 68 and 70, so as to form Deep Trench Isolation (DTI) regions 61. Specifically, the high-reflectivity metal layer 70, the metal seed layer 68, the metal blanket layer 66 and the diffusion barrier layer 65 outside of the trenches 60 are removed, so as to form the DTI regions 61. In some embodiments, from a top view, the DTI regions 61 correspond to the STI regions 32 and may form a grid including horizontal strip portions and vertical strip portions crossing each other. Each DTI regions 61 is void-free and includes, from outside to inside, a high-k layer 62, an insulating layer 64, a diffusion barrier layer 65, a metal blanket layer 66, a seed layer 68 and a high-reflectivity metal layer 70. The outer layer surrounds the sidewall and bottom of the adjacent inner layer. Upon the planarization process, the top surfaces of the layers 65, 66, 68 and 70 are flush with the top surface of the insulating layer 64. The top surfaces of the layers 65, 66, 68 and 70 are higher than the top surface of the high-k layer 62. The DTI regions are referred to as “DTI structures” or “deep trench structures” in some examples.

In the present disclosure, the conformal metal blanket layer 66 with better coverage property is provided for the subsequent metal seed layer 68, so the metal seed layer 68 can be deposited continuously across the image sensor chip 22, and thus, the high-reflectivity metal layer 70 can be effectively electroplated in the trenches 60 to form void-free DTI regions 61. In other words, due to the disposition of the metal blanket layer 66 of the disclosure, the conventional voids do not occur in such high-aspect-ratio DTI regions 61. The conventional voids may damage the stiffness and performance of the DTI regions. Besides, the DTI regions 61 of the disclosure include a high-reflectivity metallic material such as copper, so the quantum efficiency of the image sensor is greatly improved.

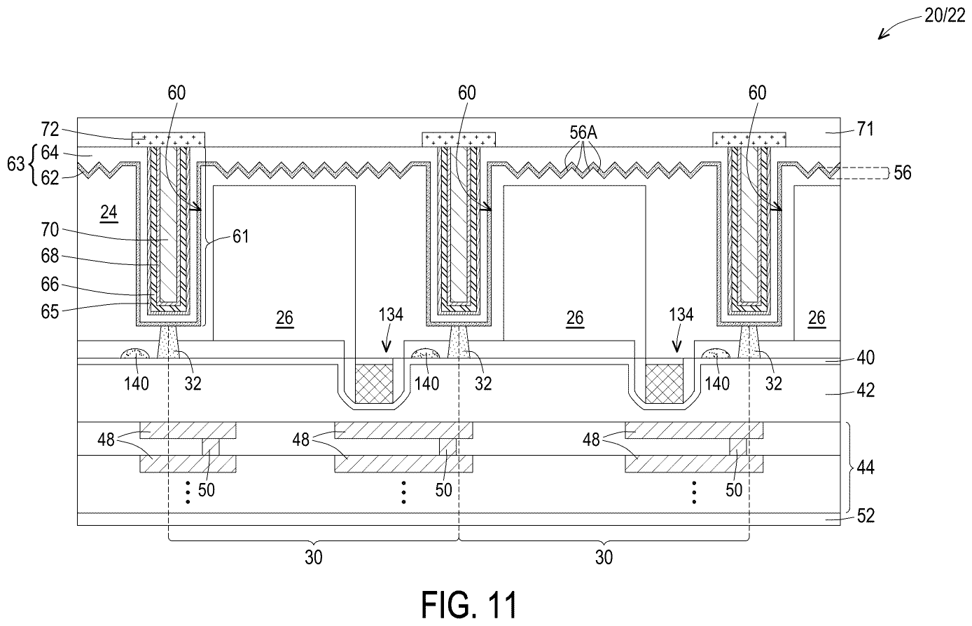

Referring to FIG. 11, caps 72 are formed over the DTI regions 61, respectively. The caps 72 are regarded as part of the DTI regions 61 in some examples. In some embodiments, the caps 72 are dielectric caps for preventing the material (such as copper) in the DTI regions 61 from being diffused upwardly. The dielectric caps may include SiN, SiC, SiCN or a combination thereof. However, the disclosure is not limited thereto. In other embodiments, the caps 72 are conductive caps for applying a small voltage (e.g., less than 3V) to the conductive caps and therefore the metal layers of the DTI regions, so as to neutralize the accumulated charges around the DTI regions caused by foregoing processes. The conductive caps may include Cu, Al, Co, Cr, W, Ti, Ta, TiN, TaN or a combination thereof. The method of forming the caps 72 includes a deposition process followed by a patterning process such as photolithography and etching processes.

Thereafter, an insulating layer 71 is formed over the caps 72. In some embodiments, the insulating layer 71 includes silicon oxide, silicon oxynitride, silicon oxycarbide, or a combination thereof. The insulating layer 71 may be formed using a conformal deposition method such as Atomic Layer Deposition (ALD) or Chemical Vapor Deposition (CVD), for example. In some embodiments, a planarization process such as a Chemical Mechanical Polish (CMP) process or a mechanical grinding process is performed to planarize the top surface of the insulating layer 71.

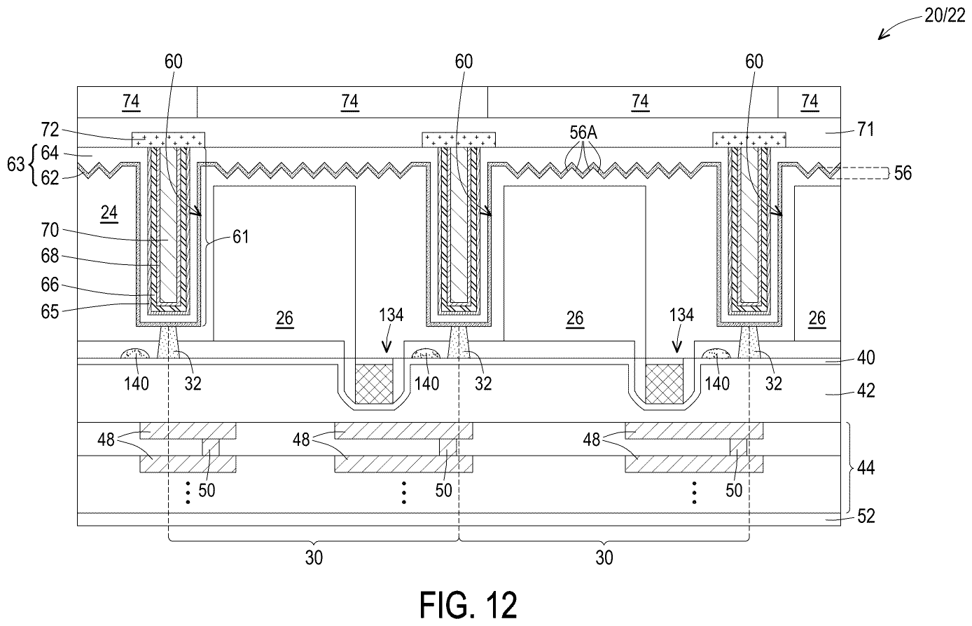

Referring to FIG. 12, multiple color filters 74 are formed over the insulating layer 71. The material of the color filter 140 is chosen to filter the light by wavelength ranges. In some embodiments, the color filters 74 may include various pixels configured with different materials such that the light in a certain wavelength range can pass through the color filter of the corresponding pixel. For example, the color filters 74 may include a red color filter, a green color filter, a blue color filter or the like.

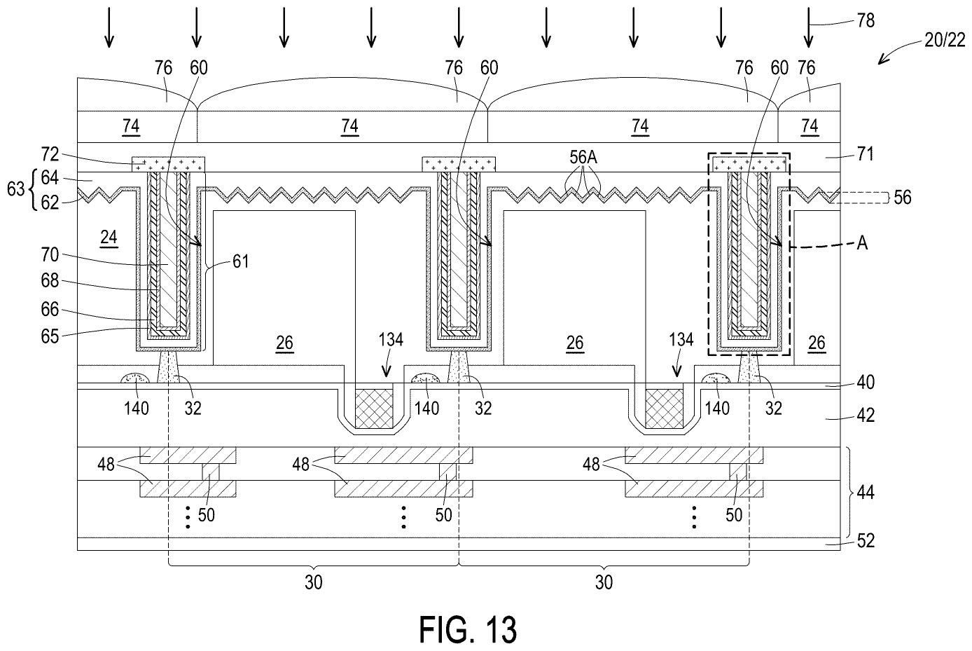

Referring to FIG. 13, multiple micro lenses 76 are then formed over the color filters 74. Each of photosensitive regions 26 is aligned to one of the color filters 74 and one of the micro-lenses 76. An image sensor chip 20 is thus completed.

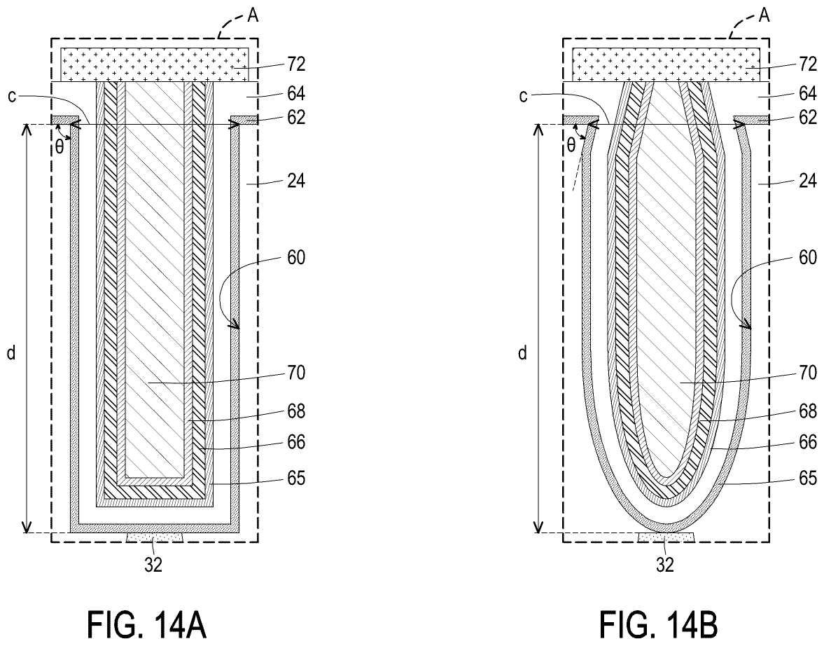

FIG. 14A and FIG. 14B illustrate enlarged local views of a region A including a DTI region of the image sensor chip of FIG. 13 in accordance with some embodiments. In FIG. 14A, the sidewall of the trench 60 is substantially perpendicular to the surface (e.g., back surface) of the semiconductor substrate 24. For example, the included angle θ between the surface of the semiconductor substrate 24 and the upper sidewall of the trench 60 may range from about 85 degrees to 95 degrees. However, the present disclosure is not limited thereto.

In other embodiments, as shown in FIG. 14B, the sidewall of the trench 60 may be slightly tilted or curved with respect to the surface (e.g., back surface) of the semiconductor substrate 24. The trench 60 may be slightly tapered at the top portion and bottom portion thereof, and hence the upper sidewall of the trench 60 is slightly tilted with respect to the surface of the semiconductor substrate 24. For example, the included angle θ between the surface of the semiconductor substrate 24 and the upper sidewall of the trench 60 may be greater than about 75 degrees and smaller than 90 degrees. Besides, the bottom of the trench 60 may be rounded and curved.

The image sensor chip 20 as shown in FIG. 13 is a BSI image sensor chip, and incoming light 78 is projected from the backside of the semiconductor substrate 24 onto the photosensitive regions 26. The light 78 may be scattered by slanted surfaces 56A, so that the light becomes more tilted inside the semiconductor substrate 24. The tilted light is more likely to be reflected (rather than penetrating through the semiconductor substrate 24). Also, by forming the high-reflectivity metal layer 70 in the DTI regions 61, the light is more likely to be reflected than absorbed by the DTI regions 61. These factors increase the light-traveling paths in the semiconductor substrate 24 (and in photosensitive regions 26), and the light has more chance to be absorbed by the photosensitive regions 26. The light-conversion efficiency (the quantum efficiency) is thus improved.

The above embodiments in which the high-reflectivity metal layer 70 completely fills the trenches 60 are provided for illustration purposes, and are not construed as limiting the present disclosure. In other embodiments, the high-reflectivity metal layer 70 does not completely fill the trenches 60, and a dielectric filling layer 80 is further formed to completely fill the trenches 60 after the high-reflectivity metal layer 70 is formed. The dielectric filling layer 80 includes silicon oxide, silicon oxynitride, silicon oxycarbide, or a combination thereof. Excess portion of the dielectric filling layer 80 is further removed during the operation of removing excess portions of layers 65, 66, 68 and 70 in FIG. 10, so as to form Deep Trench Isolation (DTI) regions 61′. Specifically, the dielectric filling layer 80, the high-reflectivity metal layer 70, the metal seed layer 68, the metal blanket layer 66 and the diffusion barrier layer 65 outside of the trenches 60 are removed, so as to form the DTI regions 61′. In some embodiments, from a top view, the DTI regions 61′ correspond to the STI regions 32 and may form a grid including horizontal strip portions and vertical strip portions crossing each other. Each DTI regions 61′ is void-free and includes, from outside to inside, a high-k layer 62, an insulating layer 64, a diffusion barrier layer 65, a metal blanket layer 66, a seed layer 68, a high-reflectivity metal layer 70 and a dielectric filling layer 80. The outer layer surrounds the sidewall and bottom of the adjacent inner layer. Upon the planarization process, the top surfaces of the layers 65, 66, 68, 70 and 80 are flush with the top surface of the insulating layer 64. The top surfaces of the layers 65, 66, 68 and 70 are higher than the top surface of the high-k layer 62.

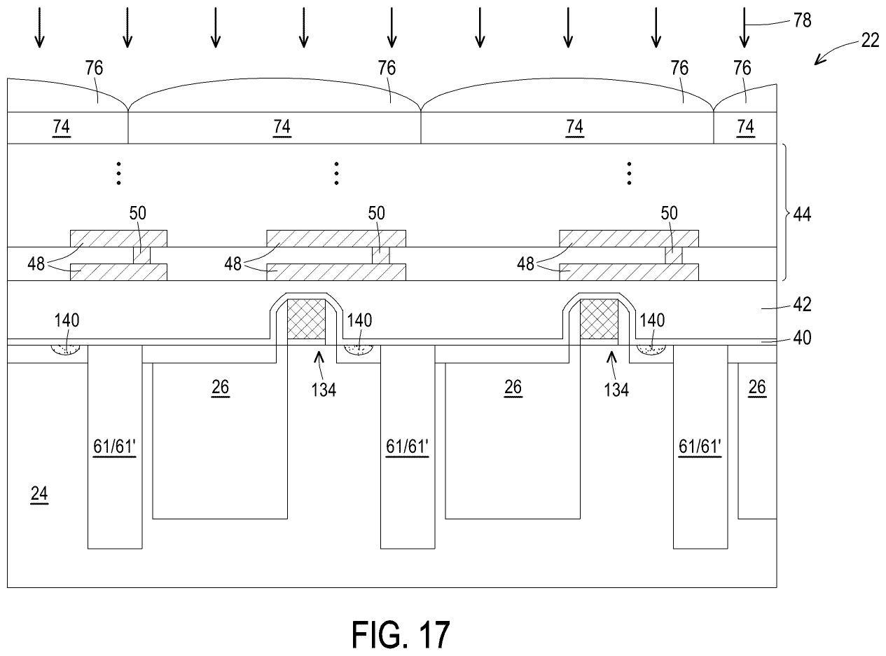

The DTI regions 61/61′ of the disclosure may also be used in other structures such as in Front Side Illumination (FSI) image sensor chips. FIG. 17 illustrates an embodiment in which DTI regions 61/61′ are formed in a FSI image sensor chip 22. Referring to FIG. 17, the FSI image sensor chip 22 includes DTI regions 61/61′. Pixel units 30 have portions formed in the regions defined by the DTI regions 61/61′. In some embodiments, STI regions are no longer formed to define active regions since the DTI regions 61/61′ include dielectric layers that may also act as (electrical) isolation regions. Each of the pixel units 30 may include a photosensitive region 26, a transfer gate transistor 134, and additional components (not shown in FIG. 17, refer to FIG. 16). The DTI regions 61/61′ extend from the major surface 24A (which is the front surface) of the semiconductor substrate 24 into an intermediate level of the semiconductor substrate 24. An interconnect structure 44 may be formed over the pixel units 30 and the DTI regions 61/61′, and includes multiple metal lines and vias in multiple dielectric layers. Color filters 74 and micro lenses 76 are formed over the interconnect structure 44, and are aligned to the pixel units 30. In the FSI image sensor chip 22, light 78 is projected to the photosensitive region 26 from the front surface of the image sensor chip 22.

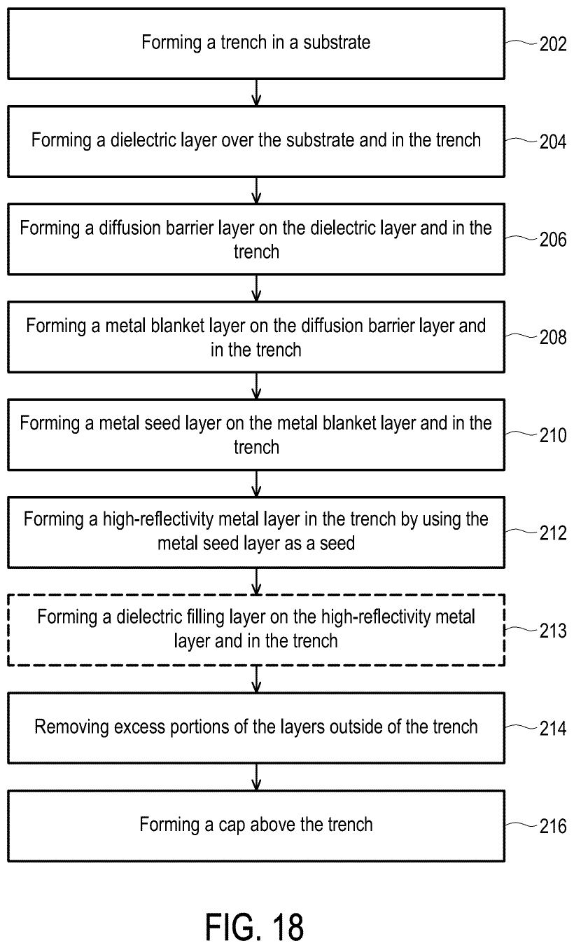

FIG. 18 illustrates a process flow for forming a deep trench isolation region in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 202, a trench is formed in a substrate. FIG. 1 to FIG. 4 illustrate views corresponding to some embodiments of act 202. In some embodiments, the trench has an aspect ratio of greater than 100.

At act 204, a dielectric layer is formed over the substrate and in the trench. FIG. 5 illustrates a view corresponding to some embodiments of act 204. In some embodiments, the dielectric layer includes a high-k layer and an insulating layer, and the high-k layer is formed between the substrate and the insulating layer.

At act 206, a diffusion barrier layer is formed on the dielectric layer and in the trench. FIG. 6 illustrates a view corresponding to some embodiments of act 206.

At act 208, a metal blanket layer is formed on the diffusion barrier layer and in the trench. FIG. 7 illustrates a view corresponding to some embodiments of act 208. In some embodiments, a method of forming the metal blanket layer includes performing Atomic Layer Deposition (ALD) or Chemical Vapor Deposition (CVD).

At act 210, a metal seed layer is formed on the metal blanket layer and in the trench. FIG. 8 illustrates a view corresponding to some embodiments of act 210.

At act 212, a high-reflectivity metal layer is formed in the trench by using the metal seed layer as a seed. FIG. 9 illustrates a view corresponding to some embodiments of act 212. In some embodiments, the high-reflectivity metal layer completely fills the trench.

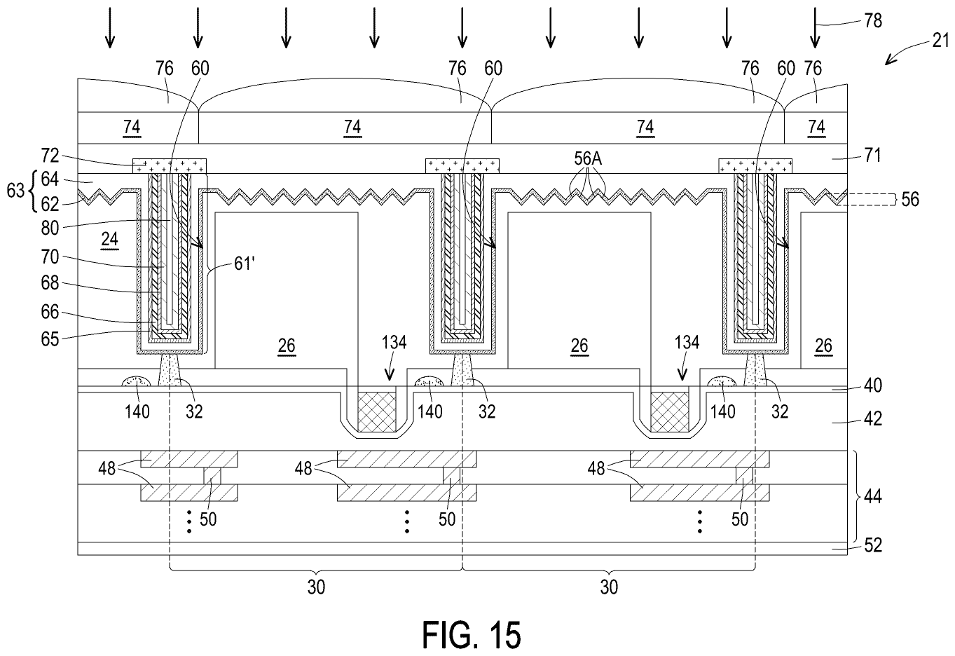

At act 213, a dielectric filling layer is formed on the high-reflectivity metal layer and in the trench. FIG. 15 illustrates a view corresponding to some embodiments of act 213. Act 213 is optional and may be omitted as needed.

At act 214, excess portions of the layers outside of the trench are removed. FIG. 10 illustrates a view corresponding to some embodiments of act 214.

At act 216, a cap is formed above the trench. FIG. 11 illustrates a view corresponding to some embodiments of act 216. In some embodiments, the cap is in physical contact with the metal blanket layer and the high-reflectivity metal layer. In some embodiments, the cap is a conductive cap electrically connected to the metal blanket layer and the high-reflectivity metal layer. In other embodiments, the cap is a dielectric cap electrically insulated from the metal blanket layer and the high-reflectivity metal layer.

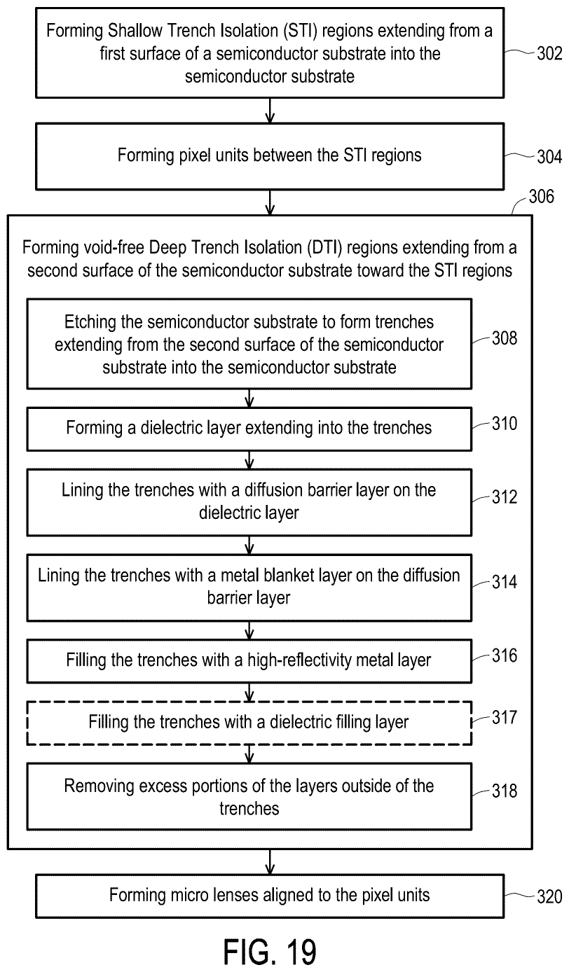

FIG. 19 illustrates a process flow for forming a deep trench isolation region in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 302, Shallow Trench Isolation (STI) regions are formed extending from a first surface of a semiconductor substrate into the semiconductor substrate. FIG. 1 illustrates a view corresponding to some embodiments of act 302.

At act 304, pixel units are formed between the STI regions. FIG. 1 illustrates a view corresponding to some embodiments of act 304.

At act 306, void-free Deep Trench Isolation (DTI) regions are formed extending from a second surface of the semiconductor substrate toward the STI regions. FIG. 2 to FIG. 14B illustrate views corresponding to some embodiments of act 306. In some embodiments, act 306 may include act 308 to act 318.

At act 308, the semiconductor substrate is etched to form trenches extending from the second surface of the semiconductor substrate into the semiconductor substrate. FIG. 4 illustrates a view corresponding to some embodiments of act 308. In some embodiments, the trenches have an aspect ratio of greater than 100.

At act 310, a dielectric layer is formed extending into the trenches. FIG. 5 illustrates a view corresponding to some embodiments of act 310.

At act 312, the trenches are lined with a diffusion barrier layer on the dielectric layer. FIG. 6 illustrates a view corresponding to some embodiments of act 312.

At act 314, the trenches are lined with a metal blanket layer on the diffusion barrier layer. FIG. 7 illustrates a view corresponding to some embodiments of act 314. In some embodiments, the metal blanket layer is formed by performing Atomic Layer Deposition (ALD) or Chemical Vapor Deposition (CVD).

At act 316, the trenches are filled with a high-reflectivity metal layer. FIGS. 8 and 9 illustrate views corresponding to some embodiments of act 316. In some embodiments, a method of forming the high-reflectivity metal layer includes: forming the metal seed layer in the trenches and on the metal blanket layer; and plating the high-reflectivity metal layer by using the metal seed layer as a seed. In some embodiments, a method of forming the metal seed layer includes performing ALD or CVD. In other embodiments, a method of forming the high-reflectivity metal layer includes plating the high-reflectivity metal layer by using the metal blanket layer as a seed.

At act 317, the trenches are filled with a dielectric filling layer. FIG. 15 illustrates a view corresponding to some embodiments of act 213. Act 213 is optional and may be omitted as needed.

At act 318, excess portions of the layers outside of the trenches are removed. FIG. 10 illustrates a view corresponding to some embodiments of act 318.

At act 320, micro lenses are formed over and aligned to the pixel units. FIG. 12 to FIG. 13 illustrate views corresponding to some embodiments of act 320.

The structures of the disclosure will be described below with reference to FIG. 13, FIG. 14A, FIG. 14B, FIG. 15 and FIG. 17. According to some embodiments of the present disclosure, a semiconductor structure 20/21/22 includes a Deep Trench Isolation (DTI) region 61/61′ disposed in a substrate 24. The DTI region 61/61′ includes, from outside to inside, a dielectric layer 63, a diffusion barrier layer 65, a metal blanket layer 66 and a high-reflectivity metal layer 70, wherein top surfaces of the dielectric layer 63, the diffusion barrier layer 65, the metal blanket layer 66, and the high-reflectivity metal layer 70 are flush with each other. In some embodiments, the DTI region 61/61′ is void free.

In some embodiments, the depth d of the DTI region 61/61′ may be equal to or greater than about 500 nm, equal to or greater than about 3,000 nm, equal to or greater than 10,000 nm, or even more. The width c of the DTI region 61/61′ may be equal to or less than about 100 nm, equal to or less than about 50 nm, equal to or less than about 30 nm, or even less. The aspect ratio (=d/c) of the DTI region 61/61′ may be greater than about 50, greater than about 100, greater than about 130 or higher, for example.

In some embodiments, the material of the diffusion barrier layer 65 is different from the material of the metal blanket layer 66. Specifically, there is an interface present between the diffusion barrier layer 65 and the metal blanket layer 66. In some embodiments, the diffusion barrier layer 65 includes TiN, TaN, TiAl, Mo₂N, RuO₂ or a combination thereof. In some embodiments, the metal blanket layer 66 includes Co, Ru, Mo, Al, Au, W, Ta or a combination thereof.

In some embodiments, a metal seed layer 68 is further included and disposed between the metal blanket layer 66 and the high-reflectivity metal layer 70. In some embodiments, the material of the metal seed layer 68 is different from the material of the metal blanket layer 66. Specifically, there is an interface present between the metal seed layer 68 and the metal blanket layer 66. In some embodiments, the metal seed layer 66 includes Cu.

In some embodiments, the semiconductor structure 20/21/22 further includes a cap 72 over the metal blanket layer 66 and the high-reflectivity metal layer 70. In some embodiments, the cap 72 is in physical contact with the metal blanket layer 66 and the high-reflectivity metal layer 70. In some embodiments, the cap 72 is a dielectric cap including SiN, SiC, SiCN or a combination thereof. In other embodiments, the cap 72 is a conductive cap including Cu, Al, Co, Cr, W, Ti, Ta, TiN, TaN or a combination thereof.

In some embodiments, the DTI region 61′ further includes a dielectric filling layer 80 surrounded by the high-reflectivity metal layer 70. Specifically, the DTI region 61′ has a sandwich structure including metal layers 65/66/68/70 interposed between dielectric layers 63/80.

The embodiments of the present disclosure have some advantageous features. The DTI region of the present disclosure is void-free and includes a high-reflectivity metallic material. Accordingly, with the use of the high-reflectivity metallic material, the quantum efficiency of the image sensors is improved. The DTI structure may be used for Backside Illumination (BSI) Complementary Metal-Oxide-Semiconductor (CMOS) image sensors or Front Side Illumination (FSI) CMOS image sensors, and may be used in other application in which deep trench isolation regions are used. The DTI region of the application may be referred to as a “deep trench region” or “deep trench structure” in some examples when it functions as an electrical component. For example, the deep trench structure of the application may function as a power rail in a semiconductor device.

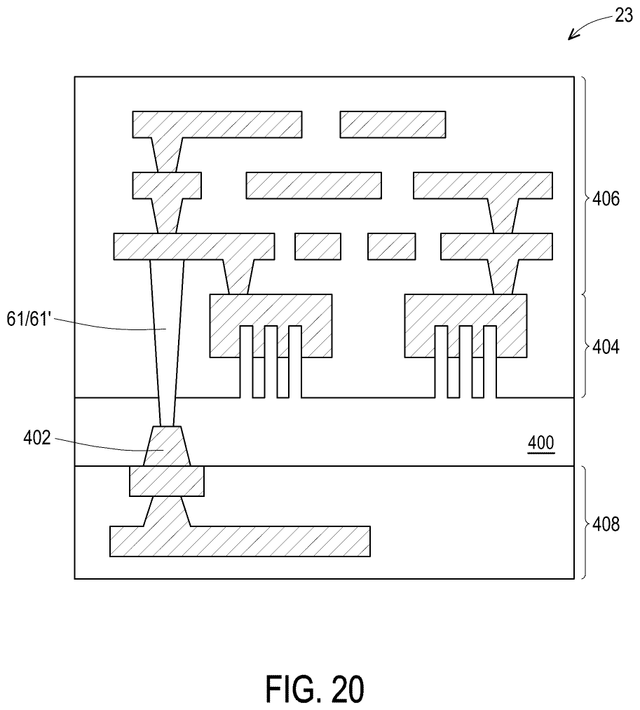

FIG. 20 illustrates a schematic cross-sectional view of a semiconductor structure in accordance with other embodiments.

In some embodiments, the semiconductor structure 23 includes a substrate 400, a through substrate via 402, a device layer 404, a front-side interconnect structure 406, a back-side interconnect structure 408 and a deep trench region 61/61′. In some embodiments, the substrate 400 may have fins protruding from the front side of the substrate, and the device layer 404 may include gates wrapping the fins of the substrate 400. However, the present disclosure is not limited thereto. In other embodiments, nanowires may be suspended between epitaxial layers on the substrate 400, and the device layer 404 may include gates wrapping the nanowires. The front-side interconnect structure 406 includes metal features embedded in dielectric layers and is electrically connected to the device layer 404. The back-side interconnect structure 408 includes metal features embedded in dielectric layers and is electrically connected to the front-side interconnect structure 406 through the through substrate via 402 and the deep trench region 61/61′.

According to some embodiments of the present disclosure, a method of forming a semiconductor structure includes: forming a trench in a substrate; forming a dielectric layer over the substrate in the trench; forming a diffusion barrier layer on the dielectric layer and in the trench; forming a metal blanket layer on the diffusion barrier layer and in the trench; forming a metal seed layer on the metal blanket layer and in the trench; forming a high-reflectivity metal layer in the trench by using the metal seed layer as a seed; and removing the diffusion barrier layer, the metal blanket layer, the metal seed layer and the high-reflectivity metal layer outside of the trench.

According to some embodiments of the present disclosure, a method of forming a semiconductor structure includes: forming Shallow Trench Isolation (STI) regions extending from a first surface of a semiconductor substrate into the semiconductor substrate; forming pixel units between the STI regions; and forming void-free Deep Trench Isolation (DTI) regions extending from a second surface of the semiconductor substrate toward the STI regions. The method of forming the DTI regions includes: etching the semiconductor substrate to form trenches extending from the second surface of the semiconductor substrate into the semiconductor substrate; forming a dielectric layer extending into the trenches; lining the trenches with a diffusion barrier layer on the dielectric layer; lining the trenches with a metal blanket layer on the diffusion barrier layer; and filling the trenches with a high-reflectivity metal layer.

According to some embodiments of the present disclosure, a semiconductor structure includes a Deep Trench Isolation (DTI) region disposed in a substrate. The DTI region includes, from outside to inside, a dielectric layer, a diffusion barrier layer, a metal blanket layer and a high-reflectivity metal layer, wherein top surfaces of the dielectric layer, the diffusion barrier layer, the metal blanket layer, and the high-reflectivity metal layer are flush with each other.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a trench in a substrate;
forming a dielectric layer over the substrate in the trench;
forming a diffusion barrier layer on the dielectric layer and in the trench;
forming a metal blanket layer on the diffusion barrier layer and in the trench;
forming a metal seed layer on the metal blanket layer and in the trench;
forming a high-reflectivity metal layer in the trench by using the metal seed layer as a seed; and
removing the diffusion barrier layer, the metal blanket layer, the metal seed layer and the high-reflectivity metal layer outside of the trench.

2. The method of claim 1, wherein the high-reflectivity metal layer completely fills the trench.

3. The method of claim 1, further comprising forming a dielectric filling layer in the trench after forming the high-reflectivity metal layer and before removing the diffusion barrier layer, the metal blanket layer, the metal seed layer and the high-reflectivity metal layer outside of the trench.

4. The method of claim 1, further comprising forming a cap above the trench after removing the diffusion barrier layer, the metal blanket layer, the metal seed layer and the high-reflectivity metal layer outside of the trench.

5. The method of claim 4, wherein the cap is in physical contact with the metal blanket layer and the high-reflectivity metal layer.

6. The method of claim 1, wherein the trench has an aspect ratio of greater than 100.

7. The method of claim 1, wherein the dielectric layer comprises a high-k layer and an insulating layer, and the insulating layer is formed between the high-k layer and the diffusion barrier layer.

8. The method of claim 1, wherein forming the metal blanket layer comprises performing Atomic Layer Deposition (ALD) or Chemical Vapor Deposition (CVD).

9. A method, comprising:
forming Shallow Trench Isolation (STI) regions extending from a first surface of a semiconductor substrate into the semiconductor substrate;
forming pixel units between the STI regions; and
forming void-free Deep Trench Isolation (DTI) regions extending from a second surface of the semiconductor substrate toward the STI regions, wherein forming the DTI regions comprises:
etching the semiconductor substrate to form trenches extending from the second surface of the semiconductor substrate into the semiconductor substrate;
forming a dielectric layer extending into the trenches;
lining the trenches with a diffusion barrier layer on the dielectric layer;
lining the trenches with a metal blanket layer on the diffusion barrier layer; and
filling the trenches with a high-reflectivity metal layer.

10. The method of claim 9, wherein the metal blanket layer is formed by performing Atomic Layer Deposition (ALD) or Chemical Vapor Deposition (CVD).

11. The method of claim 9, wherein a method of forming the high-reflectivity metal layer comprises:
forming the metal seed layer in the trenches and on the metal blanket layer; and
plating the high-reflectivity metal layer by using the metal seed layer as a seed.

12. The method of claim 9, wherein a method of forming the high-reflectivity metal layer comprises plating the high-reflectivity metal layer by using the metal blanket layer as a seed.

13. The method of claim 9, further comprising forming a cap above the trench after filling the trenches with the high-reflectivity metal layer.

14. A structure, comprising:
a Deep Trench Isolation (DTI) region disposed in a substrate, and comprising, from outside to inside, a dielectric layer, a diffusion barrier layer, a metal blanket layer and a high-reflectivity metal layer,
wherein top surfaces of the dielectric layer, the diffusion barrier layer, the metal blanket layer, and the high-reflectivity metal layer are flush with each other.

15. The structure of claim 14, wherein the DTI region has an aspect ratio of greater than 100.

16. The structure of claim 14, wherein the DTI region is void free.

17. The structure of claim 14, wherein the diffusion barrier layer comprises TiN, TaN, TiAl, MO₂N, RuO₂ or a combination thereof.

18. The structure of claim 14, wherein the metal blanket layer comprises Co, Ru, Mo, Al, Au, W, Ta or a combination thereof.

19. The structure of claim 14, further comprising a conductive cap is in physical contact with the metal blanket layer and the high-reflectivity metal layer.

20. The structure of claim 14, wherein the DTI region further comprises a dielectric filling layer surrounded by the high-reflectivity metal layer.
